(19) United States
(12) Patent Application Publication
(10) Pub. No.: US 2007/0049000 A1
(43) Pub. Date: Mar. 1, 2007

(54) Method for re-forming BGA of a semiconductor package

(76) Inventors: Jay Lin, Hsinchu Hsien (TW); Dennis Pai, Hsinchu Hsien (TW); Frank Lung, Hsinchu Hsien (TW); Hung Tsu Chang, Hsinchu Hsien (TW); Men San Lung, Hsinchu Hsien (TW)

Correspondence Address: PRO-TECHTOR INTERNATIONAL SERVICES, 20775 NORADA CT., SARATOGA, CA, 95070, US

(21) Appl. No.: 11/212,978

(22) Filed: Aug. 26, 2005

(51) Int. Cl. H01L 21/44

(52) U.S. Cl. 438/613

(57) ABSTRACT

A method for re-forming BGA of a semiconductor package includes the steps of, providing a semiconductor package element formed with balls grid array, at least one of diameter of the ball is larger than the others ; providing a jig formed with penetrated holes corresponding to the each of balls of the semiconductor package element ; providing the jig mounted to the semiconductor package element, each of balls is located within the corresponding to the penetrated holes, the at least one of bigger ball is exposed from the surface of the penetrated holes of the jig; grinding the exposed part of the balls to exact size; and re-working the processes of manufacturing BGA.

### BACKGROUND OF THE INVENTION

1. Field of the Invention

The invention relates to a method for re-forming BGA of a semiconductor package, and particular to a re-form method with increases product reliability and facilitated manufacturing processes.

2. Description of the Related Art

Usually, A semiconductor package element has a plurality of ball grid array (BGA), in the manufacture processes, if the ball grid array is formed with different size, the bigger balls must be to re-form.

A conventional method for re-form BGA is removed the bigger balls, then, reworking the manufacture processes of the BGA, thus, it is inconvenient to re-form the BGA.

### SUMMARY OF THE INVENTION

An objective of the invention is to provide a method for re-forming BGA of a semiconductor package capable of increasing the reliability of the semiconductor package element.

Another objective of the invention is to provide a method for re-forming BGA of a semiconductor package capable of facilitating manufacturing processes.

To achieve the above-mentioned object, the method includes the steps of: Providing a semiconductor package element is formed with balls grid array, at least one of diameter of the ball is larger than the others. Providing a jig is formed with penetrated holes corresponding to the each of balls of the semiconductor package element. Providing the jig mounted to the semiconductor package element, each of balls is located within the corresponding to the penetrated holes, the at least one of bigger ball is exposed from the surface of the penetrated holes of the jig. Grinding the exposed part of the balls to exact size; Re-working the processes of manufacturing BGA.

### BRIEF DESCRIPTION OF THE DRAWINGS

FIG. 1 is a first illustration view showing a method for re-forming BGA of a semiconductor package of the present invention.

FIG. 2 is a second illustration view showing a method for re-forming BGA of a semiconductor package of the present invention.

FIG. 3 is a third illustration view showing a method for re-forming BGA of a semiconductor package of the present invention.

FIG. 4 is a fourth second illustration view showing a method for re-forming BGA of a semiconductor package of the present invention.

### DETAILED DESCRIPTION OF THE INVENTION

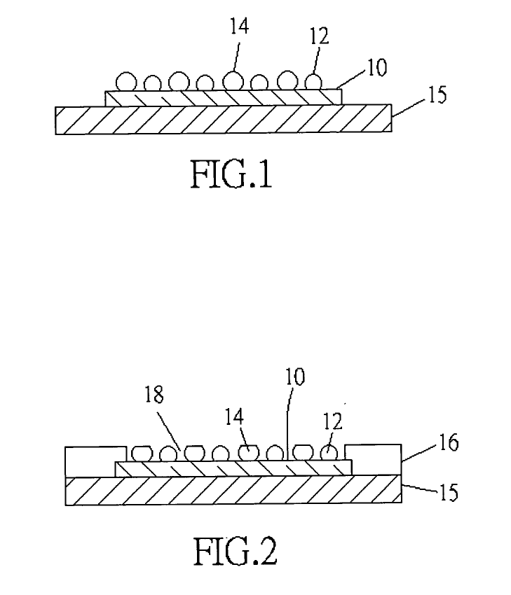

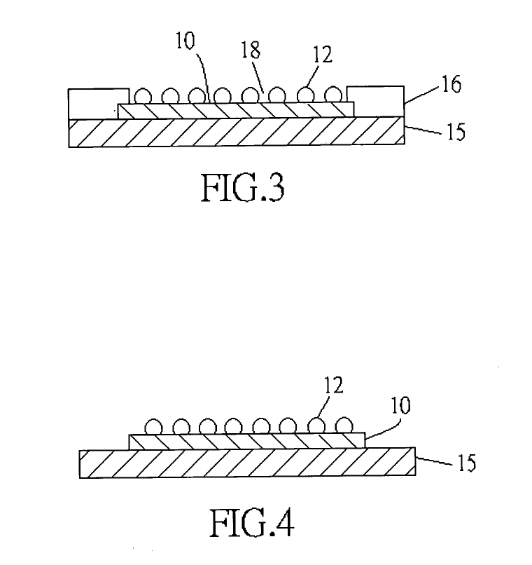

Please refer to FIG. 1 to FIG. 4, a method for re-forming BGA of a semiconductor package includes the steps of:

Providing a semiconductor package element 10 is formed with balls grid array (BGA) 12, at least one of diameter of the ball 14 is larger than the others.

Providing a metallic jig 16 is formed with penetrated holes 18 corresponding to the each of balls 12 of the semiconductor package element 10.

Providing jig 16 is mounted to the semiconductor package element 10, each of balls 12 is located within the corresponding to the penetrated holes 18, the at least one of bigger ball 14 is exposed from the surface of the penetrated holes 18 of the jig 16.

Grinding the exposed part of the balls 14 to exact size.

Re-working the processes of manufacturing BGA.

While the invention has been described by the way of an example and in terms of a preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

What is claimed is:

1. A method for re-forming BGA of a semiconductor package comprising the steps of:
Providing a semiconductor package element formed with balls grid array, at least one of diameter of the ball is larger than the others;
Providing a jig formed with penetrated holes corresponding to the each of balls of the semiconductor package element;
Providing the jig mounted to the semiconductor package element, each of balls is located within the corresponding to the penetrated holes, the at least one of bigger ball is exposed from the surface of the penetrated holes of the jig;
Grinding the exposed part of the balls to exact size; and
Re-working the processes of manufacturing BGA.

2. The method according to claim 1, wherein the jig is form of metal.
